(19) United States
(12) Patent Application Publication
(10) Pub. No.: US 2002/0061414 A1
(43) Pub. Date: May 23, 2002

(54) Method of treating latex articles and articles produced thereby

(76) Inventors: Arthur A. Krause, Winnetka, CA (US); George H. Carroll, Ventura, CA (US)

Correspondence Address: DENNIS H. LAMBERT & ASSOCIATES, 7000 View Park Drive, Burke, VA, 22015, US

(21) Appl. No.: 10/042,817

(22) Filed: Oct. 29, 2001

Related U.S. Application Data
(63) Continuation-in-part of application No. 09/677,471, filed on Oct. 2, 2000.
Application No. 09/677,471 is a continuation-in-part of application No. 09/460,772, filed on Dec. 14, 1999, now abandoned.
Application No. 09/677,471 is a continuation-in-part of application No. 09/770,251, filed on Jan. 29, 2001.
Application No. 09/770,251 is a continuation-in-part of application No. 09/339,497, filed on Jun. 24, 1999, now abandoned.

(51) Int. Cl. C23C 16/00; B32B 25/12; B32B 25/04

(52) U.S. Cl. 428/492; 427/255.23

(57) ABSTRACT

A process of treating natural rubber latex articles, and the article produced by the process, such as medical gloves, to render them safe for contact with persons sensitive to antigenic latex protein normally present in the articles. The article is manufactured in accordance with conventional methods and then exposed to an oxidizing agent, such as a halogen gas, and specifically fluorine, to eliminate or reduce to negligible levels the antigenic latex protein in the article. In a preferred embodiment, a quantity of the articles are placed in a fluorination chamber where they are contacted with a gaseous mixture containing a small proportion of fluorine gas.. The mixture introduced into the chamber is at ambient temperature and pressure, i.e., approximately 72° F. and 14.7 psi, and the contact time between the article and the gaseous mixture is very short, on the order of only about three minutes. Articles treated in accordance with the invention retain desired physical properties such as color, strength and flexibility.

### RELATED APPLICATIONS

This application is a continuation-in-part of application Ser. No. 09/677,471, filed Oct. 2, 2000, which is a continuation-in-part of application Ser. No. 09/460,772, filed Dec. 14, 1999, and a continuation-in-part of application Ser. No. 09/770,251 filed Jan. 29, 2001, which is a continuation-in-part of application Ser. No. 09/339,497, filed Jun. 24, 1999, and now abandoned.

### BACKGROUND OF THE INVENTION

1. Field of the Invention

This invention relates generally to articles made of or containing natural rubber latex and intended to be placed in contact with the human body. More specifically, the invention relates to a method of treating the articles to render the latex protein incapable of reacting with a human upon contact with the article. The treated article may also present a more effective barrier to transmission of diseases and other harmful materials and pathogens.

2. Prior Art

Many articles made from hydrocarbon elastomers, such as natural rubber latex, have long been in use. These articles include medical devices such as gloves, condoms, intrauterine contraceptive devices, endoscopic tubes, and the like. Infant pacifiers and bottle nipples, crib liners and other articles are also commonly made from natural rubber latex. Although there have been instances of adverse reactions to these latex articles, the relatively small number of instances has not previously generated a significant public health concern.

However, during the past decade or two there has been an enormous increase in use of latex gloves, due at least partially to awareness of AIDS and associated public health issues, particularly the need for protection of health care workers. A revision of OSHA regulations in 1992 also contributed to the increase in use of latex gloves. This increase in exposure to latex gloves by health care workers has accelerated the number of latex reactions. It is estimated that as many as twenty five percent (25%) of health care workers experience some type of reaction to latex products.

Natural rubber (cis-1,4-polyisoprene) is derived from liquid latex collected from the Hevea brasiliensis tree. This liquid latex contains a variety of cellular enzymes, proteins, and nucleic acids. Many of the latex proteins retain their allergenicity after the vulcanization process and are clinically significant contaminants in finished goods.

Latex sensitivity to products containing natural rubber latex can be either an irritant reaction or an allergic reaction. Irritant reactions are common and are often the result of prolonged irritation from maceration (perspiring) while wearing gloves, for example. Allergic reactions may be either a type IV reaction, which is more common and is a delayed reaction to the processing chemicals used in the manufacturing process, or a type I reaction, which is less common but is more severe. Type I reactions result from reaction to the latex proteins found in all natural rubber latex products. Reactions range from urticaria (hives), swelling of the lips, nasal congestion, and respiratory problems, to a life-threatening anaphylactic reaction. Reactions to latex can be caused by direct contact or through airborne contact. For example, latex protein particles can be aerosolized and dispersed by the donning powders used in medical gloves.

Although there is no known concentration of latex protein that would be considered safe for the extremely sensitive patient, it is important that gloves and other medical devices be manufactured with minimal levels of contaminating latex allergen. The Food and Drug Administration has proposed changing the way that natural rubber latex products are labeled, so that they would carry a warning, similar to that found on tobacco products.

The industry, particularly manufacturers of latex gloves, has responded to the problem in a variety of ways. Efforts have been made by manufacturers to produce latex gloves with reduced levels of protein content and to reduce the content of the processing chemicals. For instance, enzymes have been used by some with limited success in an effort to kill or destroy the protein. Unfortunately, this treatment process also has undesirable effects on other physical properties.

Some gloves are washed with a dilute solution of hydrochloric acid (HCL) and water to sterilize the gloves. This also has the effect of reducing the protein concentration in the gloves, but turns the gloves tan or brown in color and also has a deleterious effect on other physical properties. Gloves treated in this way are therefore less desirable, and merely reducing the level of protein or chemicals does not help those people who are particularly sensitive and reactive to any level of the allergens.

The donning powder used in gloves has been mistakenly believed to be the allergen that caused the reaction, and many companies have introduced powder-free gloves. While some people may be allergic to the cornstarch or additive that is used as the donning agent, in most instances the powder has been determined to be a transfer agent for the latex protein, which may bond with the powder particles and be dispersed into the air where patient contact can occur. Nonetheless, powder-free gloves do reduce the likelihood of an airborne transfer of the latex protein allergen.

It has been proposed to subject latex gloves to fluorination in order to alter the surface characteristics (i.e., fluorine atoms replace hydrogen atoms in the carbon spine) and improve the lubricity of the glove, whereby it would not be necessary to use a donning powder. See U.S. Pat. No. 3,992,221 to Homsy, et al. This proposal goes a long way toward eliminating the problem associated with airborne particles of donning powder and latex protein that might be carried with it, but there is no suggestion of making the glove safe for contact with persons sensitive to latex protein. Moreover, the treatment process disclosed in this patent is carried out at a relatively high temperature (at least 104° F.) and concentration of fluorine gas (up to 5:1 parts fluorine to parts inert gas), and is carried out over a relatively long period of time (e.g., more than 15 minutes dwell time after the gas mixture is introduced into the glove). Further, individual gloves are inflated with the gas mixture while the glove is on the forming mandrel so that the glove is extended by at least 10%.

Plastic articles have been fluorinated in the prior art to improve their surface characteristics for printing, and to densify the material to inhibit gassing off or evaporation of volatile compounds from the contents of plastic containers, but the concentration of fluorine used in these procedures is typically 100%, at a temperature of more than 100° F., with a time of exposure to the gas of as much as three hours.

Fluorination treatment of latex articles in the prior art is not done to eliminate or reduce the antigenic latex protein in the article so that is safe for contact with persons sensitive to the protein. This benefit of fluorination has not been recognized in the prior art. Instead, as noted above, latex articles have been fluorinated for entirely different purposes, e.g., to improve the lubricity of medical gloves to facilitate donning them whereby donning powders could be omitted.

Further, as noted above, prior art fluorination treatment of latex and plastic articles is typically carried out at much higher concentrations of fluorine, e.g., up to 100%, and at elevated temperatures and pressures, e.g., 125° F. to 132° F., and 100 psi or more, for much longer periods of time, e.g., 35 minutes to 3 hours. Treatment of latex gloves and/or condoms, in particular, at these conditions would be entirely unsuitable because of the deleterious alteration of physical properties such as strength, flexibility and color. Moreover, articles treated in accordance with these prior art processes must generally be subjected to further treatments, such as washing, before they can be used. As a consequence, these processes and the articles produced thereby are relatively expensive. Moreover, latex articles such as gloves and condoms fluorinated in accordance with these parameters would be unsuitable for use because of the change in color and reduction in strength and flexibility that would result.

Other manufacturers have introduced non-latex products in order to avoid the problem of allergic reactions to the latex proteins. For instance, some manufacturers have used vinyl to make gloves for medical and other uses, but the vinyl is not as flexible or comfortable as latex and these gloves therefore are not entirely satisfactory, especially for surgical use. Still other gloves have been made of nitrile, but these gloves are thicker than latex gloves, have a different feel, and tend to have a loose fit. Gloves made of vinyl or nitrile are therefore typically used for examination gloves.

In spite of the industry's efforts, no one has yet developed a process for treating a latex article to reduce or eliminate the antigenic latex protein present in the article while at the same time retaining all other desirable physical properties of the article.

Accordingly, there is need for a natural rubber latex product, and for a process for producing it, that is free of the problems associated with latex sensitivity, and yet which retains the desirable properties of latex.

Applicants, in their earlier copending patent application Ser. No. 09/677,471, have proposed a novel treatment of latex articles, and especially latex gloves, wherein the gloves are contacted with a gaseous mixture containing a reactive gas such as fluorine to significantly reduce the concentration of latex protein in the gloves to a level that is not reactive to persons sensitive to the latex protein, and wherein the gloves retain their desirable physical properties, such as color, strength and flexibility.

Applicants have now improved the treatment process described in their earlier application so that it is highly efficient and economical, and far superior to conventional and previous processes.

### SUMMARY OF THE INVENTION

In accordance with the invention, a natural rubber latex product is provided that is free of the problems associated with latex sensitivity.

More particularly, the invention comprises a process for treating natural rubber latex products to render them safe for use by persons sensitive to latex protein, and to articles produced thereby, while at the same time retaining other desirable attributes of such products.

In accordance with the invention, articles made from natural rubber latex, such as gloves, condoms, endoscopic tubes, intrauterine contraceptive devices, infant pacifiers, bottle nipples, and other products intended for human contact, are exposed under predetermined conditions to an oxidizing or reactive agent which alters the product in a way to eliminate or reduce to negligible levels the antigenic latex protein normally present in such articles, thereby rendering the articles safe for contact with persons sensitive to the protein The preferred reactive agent comprises a halogen gas, e.g., fluorine gas, mixed in a minor proportion with an inert gas (e.g., carbon dioxide or nitrogen), and the treatment may be carried out subsequent to manufacture of the article (post-mold fluorination), or during manufacture (in-mold fluorination). In post-mold fluorination, following manufacture the article is placed in a chamber free of extraneous oxidizing agents, and a mixture of a halogen gas such as fluorine and an inert gas such as nitrogen or carbon dioxide is introduced into the chamber for a predetermined period of time, at a predetermined pressure and temperature and at a predetermined concentration of the halogen gas, to eliminate or reduce the concentration of latex protein in the article to a level that is not reactive with a person exposed to or in contact with the article. In-mold fluorination, the article is exposed to the halogen gas or a mixture of the halogen gas and an inert gas during manufacture of the article.

Latex gloves and condoms are particularly suitable for post-mold fluorination. Surprisingly, it has been discovered that a quantity of latex gloves can be placed in bulk in a chamber for treatment in accordance with the invention. It is not necessary, as appears from the prior art, to separately expose each individual article, with the articles stretched out flat or inflated for visible exposure of the entire surface area. Similarly, latex condoms can be rolled up, or unrolled, and placed in a chamber for treatment in accordance with the invention.

It is not known with certainty at this time if the antigenic latex protein is destroyed by the reactive agent, or chemically altered, or bonded with another molecule, or simply blocked from escaping from the article. In any event, tests performed on articles treated in accordance with the invention show that the antigenic latex protein is completely absent or reduced to a negligible level. At the same time, the article retains the desirable physical characteristics and beneficial attributes of an untreated article.

Further, applicants have discovered that the fluorination treatment of latex articles, e.g., medical gloves, to eliminate or reduce to negligible levels the amount of antigenic latex protein therein, can be carried out over much shorter times, at much lower concentrations of fluorine, and at much lower temperatures and pressures, than heretofore believed possible. This not only significantly reduces the cost of such treatment, but also helps insure that other physical properties of the article, such as color, flexibility and strength, are not adversely affected. In the process of the invention, there apparently is no reaction between the fluorine and the article and a fluorine atom is not substituted for a hydrogen atom in the carbon spine, as is typically the case when latex articles are fluorinated in the prior art.

In a preferred treatment process in accordance with the invention, one or more articles to be treated are placed in a chamber. The articles need not be arranged in any particular way, and if a plurality of small articles such as latex gloves or condoms are involved, they can be simply placed loosely in bulk in the chamber, e.g., on the shelves of a rack. The chamber is then evacuated to purge it of air and other potentially oxidizing contaminants. A gaseous mixture containing 5%, by volume, of fluorine gas, and 95%, by volume, of nitrogen, is stored in a metering tank at ambient temperature (e.g., 70-76° F.) and a pressure of about 30 inches Hg. This gaseous mixture is injected into the fluorination chamber until the pressure in the metering tank decreases by an amount equivalent to the volume of the mixture desired or necessary to treat the surface area of the articles to be treated in the chamber. Normally, and depending upon atmospheric or ambient conditions, 1 inch of Hg is equivalent to 3 ft³ of the mixture. When the desired volume is reached, as indicated, for example, by the appropriate decrease in pressure in the metering tank, flow of the mixture into the chamber is stopped. The volume of the mixture thus introduced into the chamber may be equal to approximately 15%-20% of the volume of the chamber, depending upon the quantity of articles in the chamber and the total surface area to be treated. At this point, the pressure in the chamber will have increased by an amount dependent upon the volume of gaseous mixture introduced, typically to a pressure less than atmospheric. An inert gas such as CO₂ is then pumped into the chamber until the pressure in the chamber reaches about one standard atmosphere (approximately 760 torr). As soon as this pressure is reached in the chamber, evacuation of the chamber is begun and continued until all of the mixture is removed. The time elapsed from the point at which introduction of the mixture into the chamber is first started until evacuation of the mixture from the chamber is completed is approximately three minutes. The chamber is then purged by pumping CO₂ through it, followed by purging with atmospheric. The articles may then be removed from the chamber for subsequent handling and shipment to points of use.

The amount or volume of the halogen gas, e.g., fluorine, used in the treatment process of the invention depends upon the surface area to be treated. The dwell time and concentration of the halogen gas present in the gaseous mixture introduced into the chamber from the metering tank depends upon the amount or concentration of antigenic latex protein in the articles. The concentration of halogen gas in the mixture can range from about 5% up to about 28%, by volume, to achieve the desired results without any deleterious effects. Subsequent introduction of inert gas into the chamber to bring the chamber pressure up to atmospheric pressure, i.e., about 760 torr, before evacuating the chamber at the end of the treatment process, further dilutes the concentration of the halogen gas in the treatment chamber.

Because of the low concentration of reactive agent, e.g., fluorine, used, further treatment, e.g., washing, of the gloves is not necessary. Moreover, by using only that amount of fluorine calculated to be enough to treat the total surface area of articles to be treated in the chamber, i.e., to kill the antigenic protein present in the article, but not to evoke a reaction with the article, virtually all of the fluorine is consumed in the process and very little treatment or scrubbing is required of the exhaust gas in order to render it safe for discharge into the atmosphere.

Otherwise conventional latex surgical gloves treated in accordance with the invention showed a reduction in the level of antigenic latex protein therein to a level that is substantially lower that the level considered by the FDA to be safe, and these gloves did not show any loss in other desirable physical properties, such as color, strength and flexibility.

It was not expected that exposure of the latex articles to the low concentration of fluorine gas, at essentially ambient temperature and pressure, for such a short period of time, would have the desired result in the treatment of the articles.

Surprisingly, it was also found that articles such as gloves and/or condoms could be placed in bulk in the chamber and treated in accordance with the invention. Condoms could even be successfully treated when rolled up.

### DETAILED DESCRIPTION OF THE PREFERRED EMBODIMENTS

In pilot tests conducted to verify the efficacy of the invention, approximately two hundred untreated surgical latex gloves manufactured conventionally by Ansell Science and Technology of Massillon, Ohio, were obtained and sent to Fluorodynamics, Inc. (Fluorodynamics), of Taylor, Mich. for treatment in accordance with the invention in Fluorodynamics' laboratory fluorination chamber. This chamber has a volume of 13.7 ft³. Fluorodynamics placed the gloves loosely in bulk in the chamber. The chamber was then sealed and evacuated to purge it of oxygen and other potentially contaminating materials. The pressure in the chamber following purging was approximately 15 torr. A gaseous mixture containing 5%, by volume, of fluorine gas and 95%, by volume, of nitrogen gas was stored in a metering tank at ambient temperature, i.e., approximately 72° F., and at a pressure of 30 inches Hg. Based on the calculated surface area of the gloves to be treated, this gaseous mixture was injected into the chamber until the pressure in the metering tank dropped by 2 inches Hg, equivalent to approximately 2 ft.³ of the mixture. This is the volume of the mixture considered appropriate to treat the surface area of the gloves in the chamber, and is equivalent to about 15% of the volume of the chamber. At this point, the pressure in the chamber had increased to approximately 215 torr. An inert gas, CO2, was then introduced into the chamber until the pressure in the chamber was one standard atmosphere, or about 760 torr. As soon as this pressure was reached, evacuation of the chamber was immediately commenced and continued until all of the mixture had been evacuated from the chamber. The elapsed time during which the gloves were exposed to the gaseous mixture was only about three minutes. In other words, it took about 1½ minutes for the desired volume of the gaseous mixture to be pumped into the chamber, and about 1½ minutes to evacuate it. Following evacuation of the mixture from the chamber, CO₂ was pumped through the chamber to purge it, followed by pumping atmospheric air through the chamber to further purge it of any remaining traces of the treatment gas. Thereafter, the gloves were retrieved and sent to Guthrie Research Institute (Guthrie) of Sayre, Pa. for their LEAP testing service.

At Guthrie, samples were weighed and measured, after which the samples were cut to allow buffer contact with all surfaces. Extractions were performed for two hours with constant agitation at 25±5° C. in 100 mM phosphate buffered saline at a pH of 7.4 (PBS). The extraction ratio used (mis buffer/gram sample) was 5:1. The extracts were centrifuged to remove particulates and then assayed.

ELISA Inhibition Assay (ASTM D6499-00):

The samples were assayed using seven 2-fold serial dilutions in duplicate. The resulting data was calculated by using latex protein extracted from non-compounded ammoniated latex as the reference standard. The data was expressed as antigenic latex protein in micrograms/gram of sample and micrograms/dm².

Modified Lowry Assay (ASTM D 5712-99):

To perform the Modified Lowry assay, three extracts were first precipitated with deoxycholate/trichloroacetic acid/phosphotungstic acid, resuspended in NaOH and then tested using the Lowry assay. The samples were assayed using four 2-fold serial dilutions in duplicate. The resulting data was calculated by using ovalbumin as the reference standard. The data was expressed as micrograms/dm².

Results:

The tests revealed that the concentration of antigenic latex protein remaining in the gloves as measured by the ELISA Inhibition Assay (ASTM D6499-01) was only 1.2 μg/g, and the mean concentration of total latex protein remaining in the gloves as measured by the Modified Lowry Assay (ASTM Method D 5712-99), averaged over three samples, was only 50 μg/dm². These concentrations of antigenic latex protein are considered safe for contact with humans.

In comparison, untreated gloves typically have an ELISA of 54.6 μg/g and a Lowry of 198 μg/dm².

As can be clearly seen, the concentration of detectable latex protein is negligible in the latex articles treated in accordance with the invention. Moreover, this reduction in the latex protein is accomplished without any deleterious effect on other desirable physical properties of the gloves. In fact, some other desirable benefits may be obtained. For instance, powdered gloves exhibit less powder after treatment, and have virtually no powdery feel on their exterior surface. Additionally, fluorination may also sterilize the gloves, thereby obviating the necessity for further treatment to sterilize them.

Latex articles may be manufactured in accordance with conventional methods and then quickly, easily and economically treated in accordance with the invention to produce a latex article that can be safely used by persons sensitive to latex.

While particular embodiments of the invention have been illustrated and described in detail herein, it should be understood that various changes and modifications may be made to the invention without departing from the spirit and intent of the invention as defined by the scope of the appended claims.

What is claimed is:

1. A process for treating a natural rubber latex article intended for use in contact with human tissue, to eliminate or reduce to negligible levels antigenic latex protein normally present in the article, comprising the steps of:
providing a latex article manufactured in accordance with conventional techniques; and
exposing the article for a short period of time to a gaseous mixture containing a small proportion of an oxidizing agent.

2. A process as claimed in claim 1, wherein:
the article is placed in a chamber, and the gaseous mixture is introduced into the chamber for exposure of the article to the gaseous mixture.

3. A process as claimed in claim 2, wherein:
the oxidizing agent comprises up to about 5%, by volume, of the gaseous mixture, and the remaining 95% of the gaseous mixture comprises an inert gas.

4. A process as claimed in claim 3, wherein:
the oxidizing agent comprises fluorine gas and the inert gas comprises nitrogen gas.

5. A process as claimed in claim 1, wherein:
the temperature of the gaseous mixture introduced into the chamber is about 72° F. and the pressure is about 14.7 psi.

6. A process as claimed in claim 4, wherein:
the temperature of the gaseous mixture introduced into the chamber is about 72° F. and the pressure is about 14.7 psi.

7. A process as claimed in claim 1, wherein:
the article is placed in a chamber, the chamber is evacuated to purge it of oxygen, and the gaseous mixture is introduced into the chamber for exposure of the article to the gaseous mixture;
the oxidizing agent comprises up to about 5%, by volume, of the gaseous mixture, and the remaining 95% of the gaseous mixture comprises an inert gas;
the oxidizing agent comprises fluorine gas and the inert gas comprises nitrogen gas;
the temperature of the gaseous mixture introduced into the chamber is about 72° F. and the pressure is about 14.7 psi; and
the time during which the article is exposed to the gaseous mixture in the chamber is about three minutes.

8. A process as claimed in claim 7, wherein:
the gaseous mixture comprises from about 15% to about 20%, by volume, of the volume of the chamber.

9. A process for treating a natural rubber latex article to eliminate or reduce to negligible levels the latex protein normally found therein to make the article safe for contact with a person sensitive to the protein, comprising the steps of:
manufacturing a latex article in accordance with conventional techniques;
providing a chamber useful for fluorinating articles;
placing at least one said article in the chamber, sealing the chamber and purging it of extraneous oxidizing agents;
introducing a gaseous mixture containing a suitable oxidizing agent into the chamber under predetermined pressure and temperature, and at a predetermined concentration and for a predetermined period of time, to eliminate or reduce to a negligible level the latex protein normally present in the article.

10. A process as claimed in claim 9, wherein:
the suitable oxidizing agent comprises fluorine gas.

11. A process as claimed in claim 10, wherein:
the fluorine gas comprises about 5%, by volume, of the gaseous mixture, and the remaining 95%, by volume, of the gaseous mixture, comprises an inert gas.

12. A process as claimed in claim 11, wherein:
the temperature of the gaseous mixture is about 72° F. and the pressure of the gaseous mixture is about 14.7 psi.

13. A process as claimed in claim 12, wherein:
the time during which the article is exposed to the gaseous mixture in the chamber is about three minutes.

14. A process as claimed in claim 9, wherein:
a plurality of said articles are placed loosely in the chamber.

15. A process as claimed in claim 13, wherein:
the articles comprise surgical gloves.

16. A natural rubber latex article that has been treated to eliminate or reduce to a negligible level antigenic latex protein therein, and which retains the desirable physical properties such as color, strength and flexibility of an untreated latex article.
